(19) United States
(12) Patent Application Publication
(10) Pub. No.: US 2019/0196902 A1
(43) Pub. Date: Jun. 27, 2019

(54) DYNAMIC RANDOM ACCESS MEMORY AND METHOD OF OPERATING THE SAME

(71) Applicant: NANYA TECHNOLOGY CORPORATION, New Taipei City (TW)

(72) Inventors: CHUNG-HSUN LEE, NEW TAIPEI CITY (TW); HSIEN-WEN LIU, LUZHU TOWNSHIP (TW)

(21) Appl. No.: 15/904,912

(22) Filed: Feb. 26, 2018

Related U.S. Application Data
(60) Provisional application No. 62/610,341, filed on Dec. 26, 2017.

(51) Int. Cl. G06F 11/10; G11C 29/52

(52) U.S. Cl. CPC G06F 11/1068; G11C 29/52

(57) ABSTRACT

The present disclosure provides a dynamic random-access memory (DRAM) with a data correction function and a method of operating the same. The DRAM includes a memory array; a control circuit configured to receive a reading address and a defect information of the reading address; an access circuit configured to generate a reading data from the memory array according to the reading address from the control circuit; and a modifying circuit connected to the access circuit and the control circuit, wherein the modifying circuit is configured to modify a part of the reading data according to the defect information.

### PRIORITY CLAIM AND CROSS-REFERENCE

This application claims priority of U.S. provisional application Ser. No. 62/610,341 filed on Dec. 26, 2017, which is incorporated herein by reference in its entirety.

### TECHNICAL FIELD

The present disclosure relates to a dynamic random-access memory (DRAM) and a method of operating the same, and more particularly, to a dynamic random-access memory with a data correction function and a method of operating the same.

### DISCUSSION OF THE BACKGROUND

Dynamic random-access memory (DRAM) is a type of random access memory that stores each bit of data in a separate capacitor. A simplest DRAM cell comprises a single N-type metal-oxide-semiconductor (NMOS) transistor and a single capacitor. If charge is stored in the capacitor, the cell is said to store a logic HIGH, depending on the convention used. If no charge is present, the cell is said to store a logic LOW. Because the charge in the capacitor dissipates over time, DRAM systems require additional refreshing circuitries to periodically refresh the charge stored in the capacitors. Since a capacitor can store only a very limited amount of charge, in order to quickly distinguish the difference between a logic “1” and a logic “0,” two bit lines (BLs) are typically used for each bit, wherein the first bit line in the bit line pair is known as a bit line true (BLT) and the other bit line in the bit line pair is the bit line complement (BLC). The single NMOS transistor's gate is controlled by a word line (WL).

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a dynamic random-access memory (DRAM), comprising a memory array; a control circuit configured to receive a reading address and a defect information of the reading address; an access circuit configured to generate a reading data from the memory array according to the reading address from the control circuit; and a modifying circuit connected to the access circuit and the control circuit, wherein the modifying circuit is configured to modify a part of the reading data according to the defect information.

In some embodiments, the modifying circuit comprises a flip circuit configured to modify the part of the reading data by flipping at least one bit of the reading data from a first logic state to a second logic state according to the defect information.

In some embodiments, the modifying circuit further comprises an address register configured to store the defect information from the control circuit.

In some embodiments, the DRAM further comprises an error-correction circuit connected to the modifying circuit.

In some embodiments, the modifying circuit is configured to modify a first part of the reading data, and the error-correction circuit is configured to correct a second part of the reading data not modified by the modifying circuit.

Another aspect of the present disclosure provides a dynamic random-access memory (DRAM), comprising a memory array; a control circuit configured to receive a reading address; an access circuit configured to generate a reading data from the memory array according to the reading address from the control circuit; a modifying circuit comprising an address register connected to the control circuit and a flip circuit connected to the access circuit; and an error-correction circuit connected to the modifying circuit and configured to generate a defect information of the reading data; wherein the address register is connected to the error-correction circuit for receiving the defect information of the reading data, and the flip circuit is configured to modify a part of the reading data according to the defect information.

In some embodiments, the flip circuit is configured to modify the part of the reading data by flipping at least one bit of the reading data from a logic state to a second logic state according to the defect information.

In some embodiments, the error-correction circuit is connected to the control circuit, and the error-correction circuit is configured to send a signal to the control circuit if the reading data includes an uncorrectable error.

In some embodiments, the control circuit is configured to schedule a correction operation for the modifying circuit.

Another aspect of the present disclosure provides a method of operating a dynamic random-access memory, comprising the steps of: receiving a reading address; generating a reading data from a memory array of the DRAM according to the reading address; receiving a defect information of the reading address; and modifying a part of the reading data according to the defect information to generate a modified data.

In some embodiments, the step of modifying a part of the reading data comprises flipping at least one bit of the reading data from a first logic state to a second logic state according to the defect information.

In some embodiments, the method further comprises a step of storing the defect information in an address register and a step of flipping at least one bit of the reading data from a first logic state to a second logic state according to the defect information from the address register.

In some embodiments, the method further comprises a step of modifying a first part of the reading data, and a step of correcting a second part of the reading data.

In some embodiments, the step of modifying a first part of the reading data is performed by a modifying circuit, and the step of correcting a second part of the reading data is performed by an error-correction circuit.

In some embodiments, the method further comprises a step of checking whether the modified data includes an uncorrectable error.

In some embodiments, the method further comprises a step of generating an updated defect information if the modified data includes an uncorrectable error.

In some embodiments, the method further comprises a step of modifying the modified data according to the updated defect information.

In some embodiments, the method further comprises a step of scheduling a subsequent modifying operation to modify the modified data including the uncorrectable error.

In some embodiments, the step of generating a defect information of the reading address is performed by an error-correction circuit after performing an error-correction code operation.

The present disclosure performs a data correction through the flipping operation before the data enters the ECC circuit so that the ECC circuit does not need to spend too much time on data correction operations. In contrast, if the flipping operation is not used to correct the data, the ECC circuit takes a relatively longer time to correct the reading data. Traditionally, if there is a defect in one bit of a data row, then all the data stored in the entire data row is marked and replaced with another row, a process that requires additional memory.

The foregoing has outlined rather broadly the features and technical advantages of the present disclosure in order that the detailed description of the disclosure that follows may be better understood. Additional features and technical advantages of the disclosure are described hereinafter and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims The disclosure should also be understood to be connected to the figures' reference numbers, which refer to similar elements throughout the description.

FIG. 1 is a block diagram of a dynamic random-access memory (DRAM), in accordance with some embodiments of the present disclosure.

FIG. 2 is a flow chart of a method for operating a DRAM in accordance with some embodiments of the present disclosure.

FIG. 3 is a schematic block diagram illustrating a DRAM, in accordance with some embodiments of the present disclosure.

FIG. 4 is a flow chart of a method for operating a DRAM in accordance with some embodiments of the present disclosure.

FIG. 5 is a schematic block diagram illustrating a DRAM, in accordance with some embodiments of the present disclosure.

FIG. 6 is a flow chart of a method for operating a DRAM in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

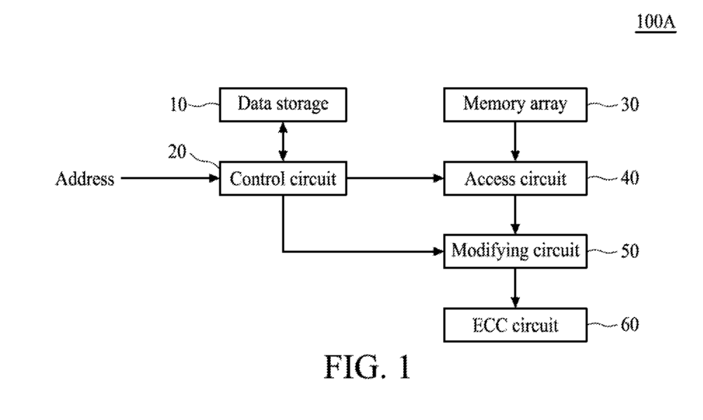

FIG. 1 is a block diagram of a dynamic random-access memory (DRAM) 100A, in accordance with some embodiments of the present disclosure. Referring to FIG. 1, in some embodiments, the DRAM 100A includes a data storage 10, a control circuit 20 connected to the data storage 10, a memory array 30, an access circuit 40 connected to the control circuit 20 and the memory array 30, a modifying circuit 50 connected to the access circuit 40 and the control circuit 20, and an error-correction code (ECC) circuit 60 connected to the modifying circuit 50.

In some embodiments, the data storage 10 is a memory configured to store defect cell information, including cell location, i.e., a row address of a defect cell containing bits therein. In some embodiments, the data storage 10 includes a defect table configured to store the defect cell information. In some embodiments, a defect bit is not able to store charge normally; for example, a defect bit, when tested, is always at low voltage, and is then identified by a testing process in the factory or during runtime. In some embodiments, the data storage 10 may be optionally disposed inside the DRAM 100A or outside the DRAM 100A.

In some embodiments, the control circuit 20 is configured to control the data storage 10, the access circuit 40 and the modifying circuit 50. In some embodiments, the control circuit 20 receives the defect cell information from the defect table of the data storage 10. In some embodiments, the control circuit 10 performs a write cycle so as to update the defect table in the data storage 10 while a testing process is performed in the factory or during runtime. In some embodiments, the control circuit 20 receives an address such as the reading address from an external device; for example, an external controller (not shown).

In some embodiments, the memory array 30 is configured to store data; for example, the memory array 30 includes a plurality of memory cells, each of which is configured for storing a bit of data, wherein the plurality of memory cells are arranged in a matrix and each one of the memory cells can be accessed using a row decoder and a column decoder.

In some embodiments, the access circuit 40 is configured to perform a read cycle for reading data from the memory array 30. In some embodiments, the access circuit 40 is configured to perform a write cycle for writing data to the memory array 30.

In some embodiments, the ECC circuit 60 is configured to perform a data correction operation. Many different error-correction codes can be applied to the data correction operation; for example, Hamming codes may be used. In some embodiments, the scenario used for ECC depends on the complexity, length of the data and the correction time. High correction performance “heavy correction” requires a longer time to process, while low correction performance “light correction” requires a shorter time to process.

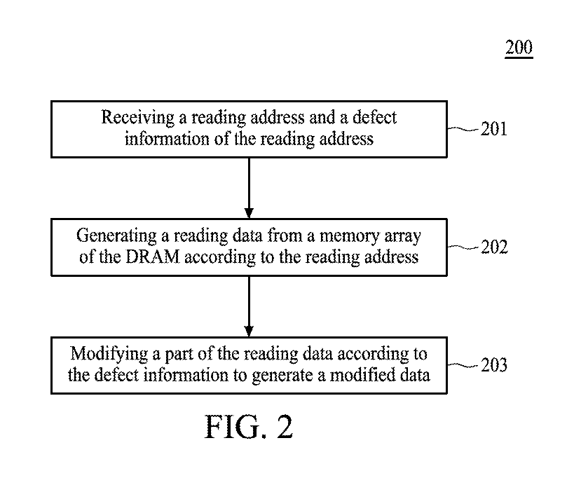

FIG. 2 is a flow chart of a method 200 for operating a DRAM such as the one shown in FIG. 1, in accordance with some embodiments of the present disclosure. The method 200 begins with an operation 201, in which a reading address and a defect information are received; for example, the control circuit 20 receives the reading address from an external controller and receives the defect information (defect address) from the data storage 10. The method 200 proceeds to an operation 202, in which a reading data is generated from a memory array according to the reading address; for example, the access circuit 40 reads data from the memory array 30 according to the reading address. Next, the method 200 proceeds to an operation 203, in which a part of the reading data is modified according to the defect address to generate a modified data; for example, the modifying circuit 50 modifies a part of the reading data according to the defect address to generate a modified data.

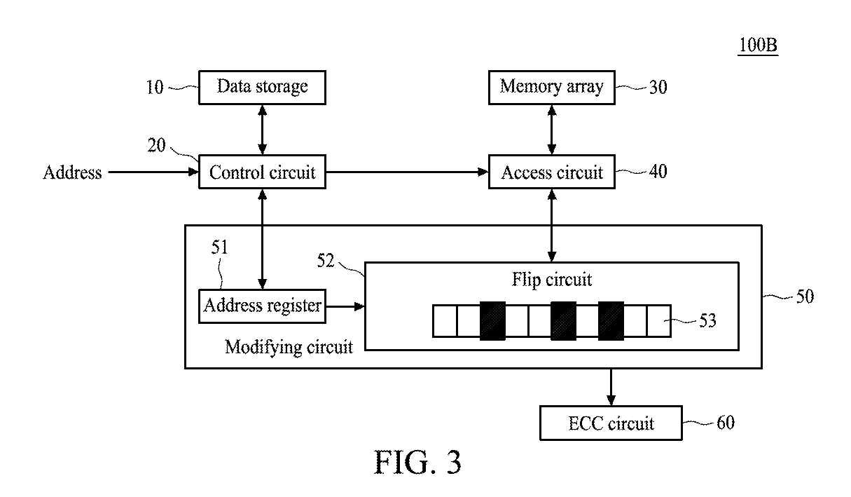

FIG. 3 is a schematic block diagram illustrating a DRAM 100B, in accordance with some embodiments of the present disclosure. In some embodiments, the modifying circuit 50 of the DRAM 100B includes an address register 51 and a flip circuit 52. In some embodiments, the address register 51 is configured to store the defect information from the control circuit 20; for example, the address register 51 stores the defect information such as the defect address (the location of defect bits) temporarily and provides the defect address to the flip circuit 52. In some embodiments, the flip circuit 52 is configured to flip at least one bit of reading data from the access circuit 40. In some embodiments, the flip circuit 52 includes a plurality of controllable inverters 53, wherein each one of inverters 53 is configured for turning a logic data from a first logic state to a second logic state; for example, from logic “0” to logic “1” (or from logic “1” to logic “0”), or directly outputting a logic signal representing the voltage high for the data bit at the defect location.

As illustrated in FIG. 3, in some embodiments, the control circuit 20 receives the reading address from an external device and receives the defect information of the reading address from a defect table of the data storage 10. In some embodiments, the control circuit 20 then checks whether the reading address includes a defect address according to the defect information from the defect table. In some embodiments, the defect table stores defect location information of the defect address in the data storage 10. In some embodiments, the data storage 10 is a non-volatile memory, which can be inside or outside the DRAM 100B.

In some embodiments, if the reading address includes a defect address, the control circuit 20 configures the modifying circuit 50, which includes the address register 51 and the flip circuit 52, according to the defect information. In some embodiments, the defect addresses (the location of defect bits) provided by the control circuit 20 are then stored in the address register 51. In some embodiments, the access circuit 40 then reads data from the memory array 30 according to the reading address provided by the control circuit 20, and the access circuit 40 transmits the reading data to the flip circuit 52 of the modifying circuit 50. In some embodiments, the flip circuit 52 of the modifying circuit 50 receives the reading data and flips at least one defect bit according to the defect address stored in the address register 51. In some embodiments, after the flipping operation, the flip circuit 52 outputs the modified data to the ECC circuit 60 for further processing to provide corrected data. In some embodiments, the flip operation of the flip circuit 52 is configured for turning logic data from a first logic state to a second logic state; for example, from logic “0” to logic “1” (or from logic “1” to logic “0”), or directly outputting a logic signal representing the voltage high for the data bit at the defect location.

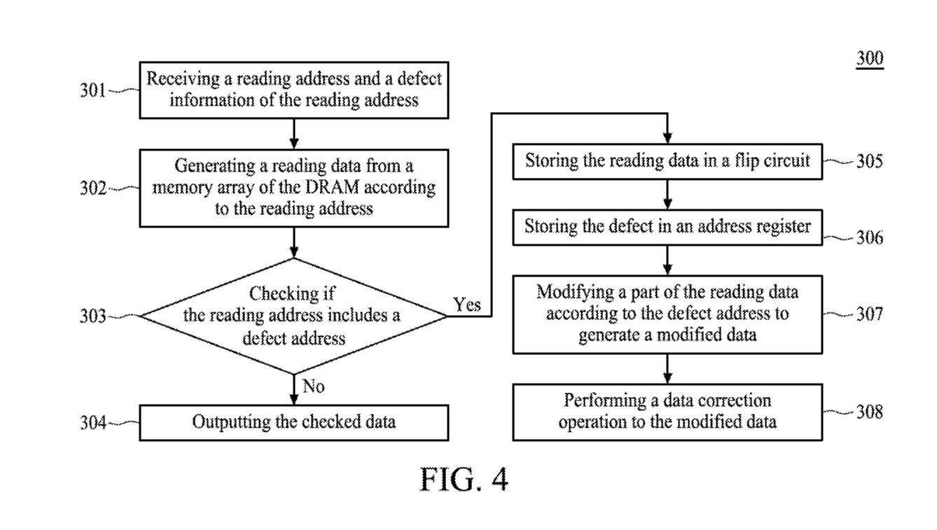

FIG. 4 is a flow chart of a method 300 for operating a DRAM such as the DRAM 100B shown in FIG. 3, in accordance with some embodiments of the present disclosure. The method 300 begins with an operation 301, in which a reading address and a defect information are received; for example, the control circuit 20 receives the reading address from an external controller and the defect information (e.g., defect address) from the data storage 10. Subsequently, the method 300 proceeds to an operation 302, in which a reading data from a memory array of the DRAM is generated according to the reading address; for example, the access circuit 40 reads data from the memory array 30 of the DRAM 100B according to the reading address. Next, the method 300 proceeds to an operation 303, in which it is determined whether the reading address includes a defect address; for example, the control circuit 20 checks whether the reading address includes a defect address according to the defect information. If the checking result is negative, the method 300 proceeds to an operation 304, in which the checked data is outputted.

If the checking result is affirmative, the method 300 proceeds to an operation 305, in which the reading data is stored in a flip circuit; for example, the reading data is stored in the flip circuit 52. Next, the method 300 proceeds to an operation 306, in which the defect address is stored in an address register; for example, the defect address (the location of defect bits) provided by control circuit 20 is stored in the address register 51.

Subsequently, the method 300 proceeds to an operation 307, in which a first part of the reading data is modified according to the defect address to generate a modified data; for example, the flip circuit 52 of the modifying circuit 50 modifies a first part of the reading data by flipping the data located at the defect address to generate a modified data. In some embodiments, the flip circuit 52 receives the reading data and flips at least one defect bit according to the defect address stored in the address register 51. In some embodiments, after the flipping operation, the flip circuit 52 outputs the modified data to the ECC circuit 60 for further data correction. In some embodiments, after the flip circuit 52 outputs the modified data, the method 300 proceeds to an operation 308, in which a data correction operation is performed on the modified data to modify a second part of the reading data; for example, the ECC circuit 60 performs a data correction operation to modify a second part of the reading data (i.e., data stored in a bit other than the defect bit).

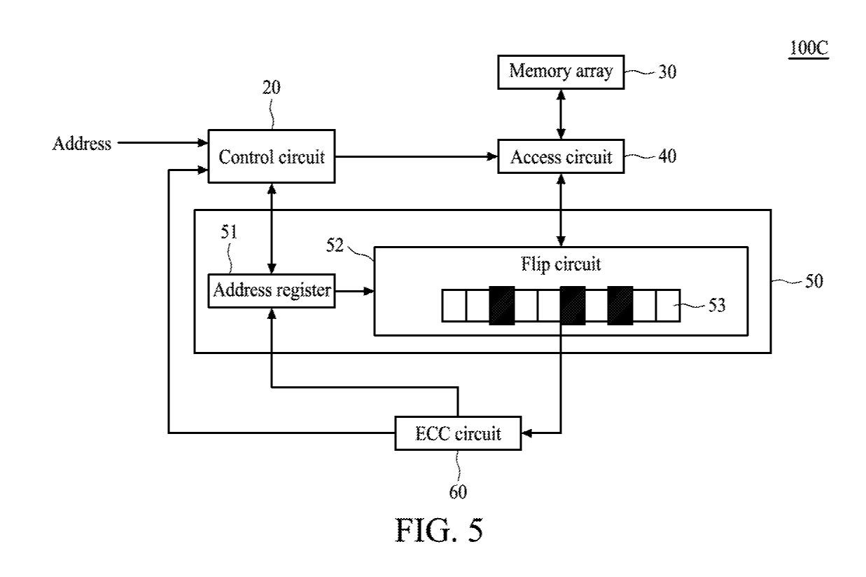

FIG. 5 is a schematic block diagram illustrating a DRAM 100C, in accordance with some embodiments of the present disclosure. In some embodiments, the control circuit 20, as illustrated in FIG. 1, is configured to control the access circuit 40 and the modifying circuit 50. As mentioned above, the control circuit 20 controls the access circuit 40 to read data from the memory array 30 according to the reading address, and the access circuit 40 then transmits the reading data to the flip circuit 52 of the modifying circuit 50. In some embodiments, the flip circuit 52 temporarily stores the reading data and outputs the reading data to the ECC circuit 60. In some embodiments, the ECC circuit 60 checks whether an error exists. If there is no error, then the ECC circuit 60 outputs the correct reading data; if a correctable error exists, then the ECC circuit 60 corrects the error and outputs the corrected reading data. In some embodiments, if an uncorrectable error exists, the ECC circuit 60 provides a signal to the control circuit 20 for further data correction operation. In some embodiments, the control circuit 20 schedules the read operation and the correction operation.

In some embodiments, the ECC circuit 60 provides the defect information (error bit information), including the address of the error bit, to the address register 51, and the flip circuit 52 then flips at least one error bit of the stored data according to the error bit information from the address register 51. In some embodiments, after the flipping operation, the flip circuit 52 outputs the modified data. In some embodiments, the flip circuit 52 provides the modified data to the ECC circuit 60 to determine whether there is no error or the error is correctable; if the checking result is affirmative, the ECC circuit 60 then outputs the correct or corrected data; if an uncorrectable error exists, the ECC circuit 60 provides a signal to the control circuit 20 for another data correction operation, for example, a second flip operation can be performed to flip additional error bits.

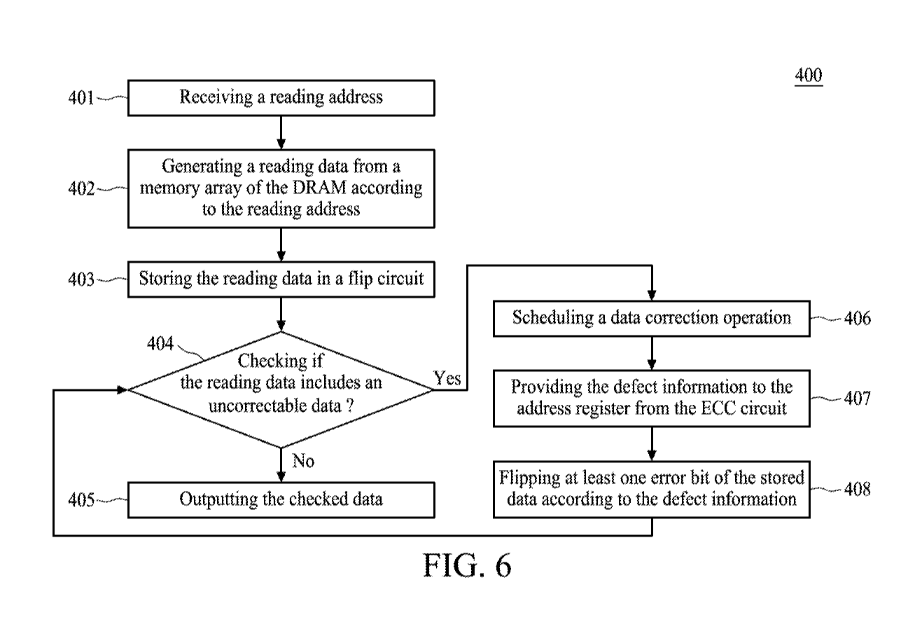

FIG. 6 is a flow chart of a method 400 for operating a DRAM such as the DRAM 100C shown in FIG. 5, in accordance with some embodiments of the present disclosure. The method 400 begins with an operation 401, in which a reading address is received from an external device; for example, the control circuit 20 receives a reading address from an external controller. The method 400 proceeds to an operation 402, in which a reading data is generated from a memory array according to the reading address; for example, the access circuit 40 reads data from the memory array 30 according to the reading address from the control circuit 20. Next, the method 400 proceeds to an operation 403, in which the reading data is stored in a flip circuit; for example, the access circuit 40 transmits the reading data to the flip circuit 52 and the flip circuit 52 temporarily stores the reading data.

Next, the method 400 proceeds to an operation 404, in which it is determined whether the reading data includes an uncorrectable error; for example, the ECC circuit 60 checks whether the reading data includes an uncorrectable error. If the checking result is negative, the method 400 proceeds to an operation 405, in which the checked data is outputted and the temporarily stored reading data in the flip circuit 52 is discarded. If the checking result is affirmative, the method 400 proceeds to an operation 406, in which a data correction operation is scheduled; for example, the control circuit 20 is directed by the ECC circuit 60 to schedule the reading operation and the data correction operation. Subsequently, the method 400 proceeds to an operation 407, in which the defect information is provided to the address register 51; for example, the ECC circuit 60 provides the defect information, i.e., the error bit information, to the address register 51. Next, the method 400 proceeds to an operation 408, in which at least one error bit of the stored data is flipped according to the defect information; for example, the flip circuit 52 flips at least one error bit of the stored data according to the defect information and then outputs the modified data to the ECC circuit 60. Subsequently, the method 400 proceeds back to the operation 404, in which it is determined whether the modified data still includes an uncorrectable error. and repeats the data correction cycle (e.g., the steps 406, 407, and 408) if the modified data still contains an uncorrectable error.

The present disclosure performs a data correction through the flipping operation before the data enters the ECC circuit 60 so that the ECC circuit 60 does not need to spend too much time on data correction operations. In contrast, if the flipping operation is not used to correct the data, the ECC circuit 60 takes a longer time to correct the reading data. Traditionally, if there is a defect in one or more bit of a data row, the entire data row are marked and replaced with another row, a process which requires more memory.

One aspect of the present disclosure provides a dynamic random-access memory (DRAM), comprising a memory array; a control circuit configured to receive a reading address and a defect information of the reading address; an access circuit configured to generate a reading data from the memory array according to the reading address from the control circuit; and a modifying circuit connected to the access circuit and the control circuit, wherein the modifying circuit is configured to modify a part of the reading data according to the defect information.

Another aspect of the present disclosure provides a dynamic random-access memory (DRAM), comprising a memory array; a control circuit configured to receive a reading address; an access circuit configured to generate a reading data from the memory array according to the reading address from the control circuit; a modifying circuit comprising an address register connected to the control circuit and a flip circuit connected to the access circuit; and an error-correction circuit connected to the modifying circuit and configured to generate a defect information of the reading data; wherein the address register is connected to the error-correction circuit for receiving the defect information of the reading data, and the flip circuit is configured to modify a part of the reading data according to the defect information.

Another aspect of the present disclosure provides a method of operating a dynamic random-access memory, comprising the steps of: receiving a reading address; generating a reading data from a memory array of the DRAM according to the reading address; receiving a defect information of the reading address; and modifying a part of the reading data according to the defect information to generate a modified data.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A dynamic random-access memory (DRAM), comprising:
a memory array;
a control circuit configured to receive a reading address and a defect information of the reading address;
an access circuit configured to generate a reading data from the memory array according to the reading address from the control circuit; and
a modifying circuit connected to the access circuit and the control circuit, wherein the modifying circuit is configured to modify a part of the reading data according to the defect information.

2. The DRAM of claim 1, wherein the modifying circuit comprises a flip circuit configured to modify the part of the reading data by flipping at least one bit of the reading data from a first logic state to a second logic state according to the defect information.

3. The DRAM of claim 2, wherein the modifying circuit further comprises an address register configured to store the defect information from the control circuit.

4. The DRAM of claim 1, further comprising an error-correction circuit connected to the modifying circuit.

5. The DRAM of claim 4, wherein the modifying circuit is configured to modify a first part of the reading data, and the error-correction circuit is configured to correct a second part of the reading data not modified by the modifying circuit.

6. A dynamic random-access memory (DRAM), comprising:
a memory array;
a control circuit configured to receive a reading address;
an access circuit configured to generate a reading data from the memory array according to the reading address from the control circuit;
a modifying circuit comprising an address register connected to the control circuit and a flip circuit connected to the access circuit; and
an error-correction circuit connected to the modifying circuit and configured to generate a defect information of the reading data;
wherein the address register is connected to the error-correction circuit for receiving the defect information of the reading data, and the flip circuit is configured to modify a part of the reading data according to the defect information.

7. The DRAM of claim 6, wherein the flip circuit is configured to modify the part of the reading data by flipping at least one bit of the reading data from a logic state to a second logic state according to the defect information.

8. The DRAM of claim 6, wherein the error-correction circuit is connected to the control circuit, and the error-correction circuit is configured to send a signal to the control circuit if the reading data includes an uncorrectable error.

9. The DRAM of claim 6, wherein the control circuit is configured to schedule a correction operation for the modifying circuit.

10. A method of operating a dynamic random-access memory, comprising the steps of:
receiving a reading address;
generating a reading data from a memory array of the DRAM according to the reading address;
receiving a defect information of the reading address; and
modifying a part of the reading data according to the defect information to generate a modified data.

11. The method of claim 10, wherein the step of modifying a part of the reading data comprises flipping at least one bit of the reading data from a first logic state to a second logic state according to the defect information.

12. The method of claim 10, further comprising a step of storing the defect information in an address register and a step of flipping at least one bit of the reading data from a first logic state to a second logic state according to the defect information from the address register.

13. The method of claim 10, comprising a step of modifying a first part of the reading data, and a step of correcting a second part of the reading data.

14. The method of claim 10, wherein the step of modifying a first part of the reading data is performed by a modifying circuit, and the step of correcting a second part of the reading data is performed by an error-correction circuit.

15. The method of claim 10, further comprising a step of determining whether the modified data includes an uncorrectable error.

16. The method of claim 15, further comprising a step of generating an updated defect information if the modified data includes an uncorrectable error.

17. The method of claim 16, further comprising a step of modifying the modified data according to the updated defect information.

18. The method of claim 10, further comprising a step of scheduling a subsequent modifying operation to modify the modified data including the uncorrectable error.

19. The method of claim 10, wherein the step of generating a defect information of the reading address is performed by an error-correction circuit after performing an error-correction code operation.
